(19) United States
(12) Patent Application Publication
(10) Pub. No.: US 2006/0099774 A1
(43) Pub. Date: May 11, 2006

(54) Method of laser processing a gallium nitride substrate

(75) Inventor: Hitoshi Hoshino, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/261,599

(22) Filed: Oct. 31, 2005

(30) Foreign Application Priority Data
Nov. 8, 2004 (JP) 2004-323298

(51) Int. Cl. H01L 21/78; H01L 21/301; H01L 21/46

(52) U.S. Cl. 438/463

(57) ABSTRACT

A method of laser processing a gallium nitride substrate, for forming a dividing groove along dividing lines that section devices formed on a gallium nitride substrate, the method comprising the step of applying a pulse laser beam having a wavelength of 200 to 365 nm along the dividing lines that section the devices formed on the gallium nitride substrate.

### FIELD OF THE INVENTION

The present invention relates to a laser processing method for forming a dividing groove along dividing lines that section devices formed on a gallium nitride substrate.

### DESCRIPTION OF THE PRIOR ART

In the production process of an optical device such as a blue light-emitting diode, laser diode or the like, a plurality of areas are sectioned by dividing lines called “streets” arranged in a lattice pattern on the front surface of a sapphire substrate, and a gallium nitride optical element is formed in each of the sectioned areas. Individual optical devices each of which has a gallium nitride optical element formed thereon are manufactured by dividing this sapphire substrate along the dividing lines.

Cutting along the dividing lines of the above sapphire substrate is generally carried out by using a cutting machine called “dicer”. This cutting machine comprises a chuck table for holding a workpiece such as a sapphire substrate, a cutting means for cutting the workpiece held on the chuck table, and a cutting-feed means for moving the chuck table and the cutting means relative to each other. The cutting means comprises a rotary spindle, a cutting blade mounted on the spindle and a drive mechanism for rotary-driving the rotary spindle. The cutting blade is composed of a disk-like base and an annular cutting-edge which is mounted on the side wall peripheral portion of the base and formed as thick as about 20 μm by fixing diamond abrasive grains having a diameter of about 3 μm to the base by electroforming.

Since the sapphire substrate has high Mohs hardness, however, cutting with the above cutting blade is not always easy. Further, as the cutting blade has a thickness of about 20 μm, the dividing lines for sectioning devices must have a width of about 50 μm. Therefore, in the case of a device measuring 300 μm×300 μm, the area ratio of the streets to the device becomes 14 %, thereby reducing productivity.

Meanwhile, U.S. Pat. No. 6,580,054 discloses a technology for forming a dividing groove along dividing lines by applying a pulse laser beam having a wavelength of 560 nm or less, preferably 532 nm, along the dividing lines of a sapphire substrate.

Further, to improve the brightness of an optical device, a technology for forming optical elements directly on a gallium nitride substrate without using a sapphire substrate has recently been developed.

It has been found, however, that even when a pulse laser beam having a wavelength of 532 nm is applied along the dividing lines of a gallium nitride substrate by using the above technology for forming a dividing groove in the gallium nitride substrate, a desired groove cannot be formed along the dividing lines.

### SUMMARY OF THE INVENTION

It is an object of the present invention to provide a method of laser processing a gallium nitride substrate, which is capable of forming a desired dividing groove along dividing lines that section devices formed on a gallium nitride substrate.

To attain the above object, according to the present invention, there is provided a method of laser processing a gallium nitride substrate, for forming a dividing groove along dividing lines that section devices formed on a gallium nitride substrate, the method comprising the step of applying a pulse laser beam having a wavelength of 200 to 365 nm along the dividing lines that section the devices formed on the gallium nitride substrate.

According to the present invention, since the wavelength of the pulse laser beam to be applied along the dividing lines that section devices formed on the gallium nitride substrate is set to 200 to 365 nm, a dividing groove can be surely formed along the dividing lines that section devices formed on the gallium nitride substrate.

### BRIEF DESCRIPTION OF THE DRAWINGS

FIG. 1 is a perspective view of an optical device wafer as a workpiece;

FIG. 2 is a perspective view showing a state where the optical device wafer shown in FIG. 1 has been put on a protective tape affixed to an annular frame;

FIG. 3 is a perspective view of the principal section of a laser beam processing machine for carrying out the laser processing method of the present invention;

FIG. 4 is a block diagram showing the constitution of a laser beam application means provided in the laser beam processing machine shown in FIG. 3;

FIG. 5 is a schematic diagram for explaining the focusing spot diameter of a laser beam applied from the laser beam application means shown in FIG. 4; and

FIG. 6 is an explanatory diagram showing the laser beam application step which is carried out by the laser beam processing machine shown in FIG. 3; and

FIG. 7 is an enlarged sectional view of the optical device wafer having a dividing groove formed by carrying out the laser beam application step shown in FIG. 6.

### DETAILED DESCRIPTION OF THE PREFERRED EMBODIMENT

A preferred embodiment of the method of laser processing a gallium nitride substrate according to the present invention will be described hereinunder in more detail with reference to the accompanying drawings.

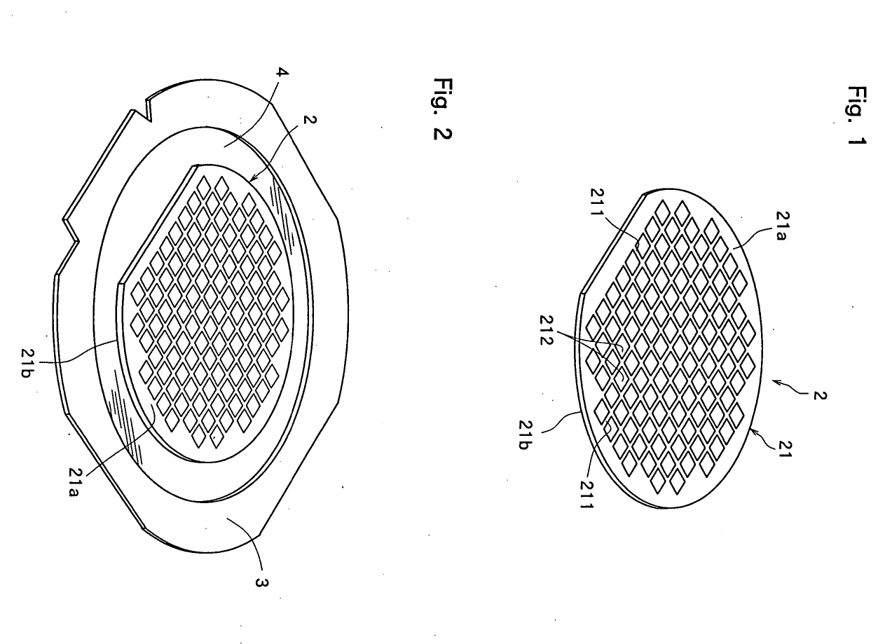

FIG. 1 is a perspective view of an optical device wafer 2 as a workpiece to be laser processed. In the optical device wafer 2 shown in FIG. 1, a plurality of areas are sectioned by a plurality of dividing lines 211 formed in a lattice pattern on the front surface 21a of a gallium nitride (GaN) substrate 21, and an optical device comprising a gallium nitride optical element 212 is formed in each of the sectioned areas.

The back surface 21b of the optical device wafer 2 constituted as described above is put on the surface of a protective tape 4 mounted on an annular frame 3 as shown in FIG. 2 (wafer affixing step) . Therefore, the front surface 21a having the gallium nitride optical elements 212 formed thereon, of the optical device wafer 2 faces up. In the illustrated embodiment, acrylic resin adhesive is coated on the surface of a 70 μm-thick polyvinyl chloride (PVC) sheet backing of the above protective tape 4 to a thickness of about 5 μm.

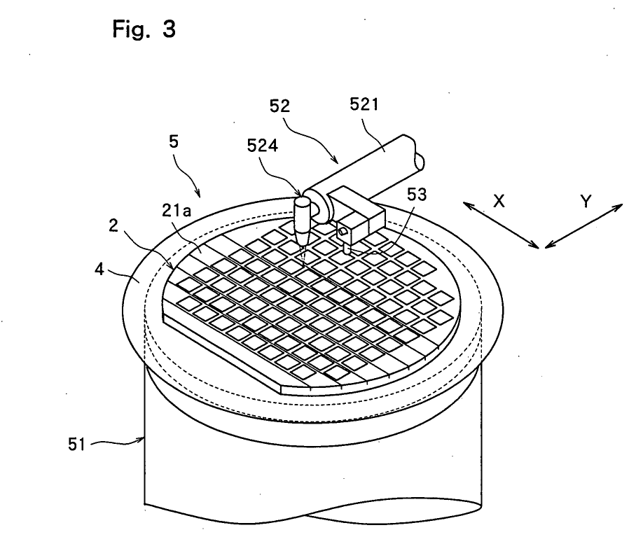

To carry out laser processing for forming a dividing groove along the dividing lines 211 by applying a laser beam along the dividing lines 211 of the above optical device wafer 2, a laser beam processing machine 5 shown in FIGS. 3 to 5 is used. The laser beam processing machine 5 shown in FIGS. 3 to 5 comprises a chuck table 51 for holding a workpiece, a laser beam application means 52 for applying a laser beam to the workpiece held on the chuck table 51, and an image pick-up means 53 for picking up an image of the workpiece held on the chuck table 51. The chuck table 51 is so constituted as to suction-hold the workpiece and is designed to be moved in a processing-feed direction indicated by an arrow X in FIG. 3 by a processing-feed means and in an indexing-feed direction indicated by an arrow Y by an indexing-feed means that is not shown.

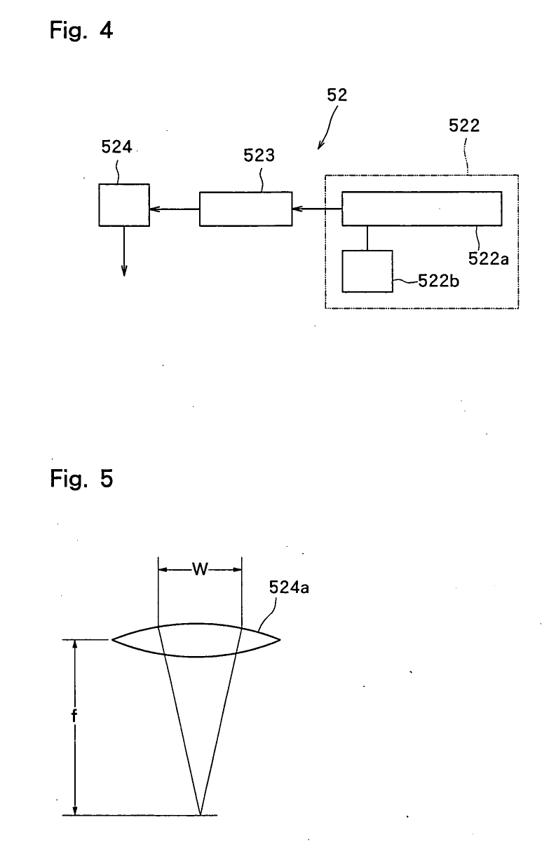

The above laser beam application means 52 has a cylindrical casing 521 arranged substantially horizontally. In the casing 521, there are installed a pulse laser beam oscillation means 522 and a transmission optical system 523, as shown in FIG. 4. The pulse laser beam oscillation means 522 is constituted by a pulse laser beam oscillator 522a composed of a YAG laser oscillator or YVO4 laser oscillator and a repetition frequency setting means 522b connected to the pulse laser beam oscillator 522a. The transmission optical system 523 comprises suitable optical elements such as a beam splitter, etc. A condenser 524 housing condensing lenses (not shown) constituted by a combination of lenses that may be formation known per se is attached to the end of the above casing 521 . A laser beam oscillated from the above pulse laser beam oscillation means 522 reaches the condenser 524 through the transmission optical system 523 and is applied to the workpiece held on the above chuck table 51 from the condenser 524 at a predetermined focusing spot diameter D. This focusing spot diameter D is defined by the expression D (μm)=4×λ×f/ (π×W) (wherein λ is the wavelength (λm) of the pulse laser beam, W is the diameter (mm) of the pulse laser beam applied to an objective lens 524a, and f is the focusing distance (mm) of the objective lens 524a) when the pulse laser beam showing a Gaussian distribution is applied through the objective lens 524a of the condenser 524, as shown in FIG. 5.

The image pick-up means 53 attached to the end of the casing 521 constituting the above laser beam application means 52 transmits an image signal to a control means that is not shown.

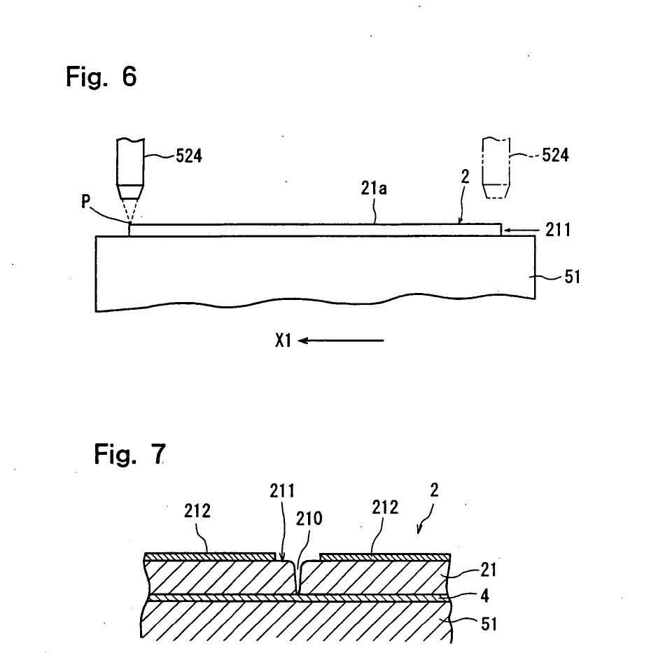

A description will be subsequently given of laser processing for forming a dividing groove along the dividing lines 211 by applying a laser beam along the dividing lines 211 of the optical device wafer 2 with the above laser beam processing machine 5 with reference to FIG. 3, FIG. 6 and FIG. 7.

The optical device wafer 2 put on the surface of the protective tape 4 mounted on the annular frame 3 as shown in FIG. 2 is first placed on the chuck table 51 of the laser beam processing machine 5 shown in FIG. 3 and is suction-held on the chuck table 51. Although the annular frame 3 mounted on the protective tape 4 is not shown in FIG. 3, it is held on a suitable frame holding means arranged on the chuck table 51.

The chuck table 51 suction-holding the optical device wafer 2 as described above is brought to a position right below the image pick-up means 53 by the processing-feed means that is not shown. After the chuck table 51 is positioned right below the image pick-up means 53, alignment work for detecting the area to be processed of the optical device wafer 2 is carried out by the image pick-up means 53 and the control means that is not shown. That is, the image pick-up means 53 and the control means (not shown) carry out image processing such as pattern matching, etc. to align a dividing line 211 formed in a predetermined direction of the optical device wafer 2 with the condenser 524 of the laser beam application means 52 for applying a laser beam along the dividing line 211, thereby performing the alignment of a laser beam application position. The alignment of the laser beam application position is also carried out on dividing lines 211 formed on the optical device wafer 2 in a direction perpendicular to the predetermined direction similarly.

After the dividing line 211 formed on the optical device wafer 2 held on the chuck table 51 is detected and the alignment of the laser beam application position is carried out as described above, the chuck table 51 is moved to bring one end (left end in FIG. 6) of the predetermined dividing line 211 to a position right below the condenser 524, as shown in FIG. 6. The chuck table 51, that is, the optical device wafer 2 is then moved in the direction indicated by the arrow Xl in FIG. 6 at a predetermined processing-feed rate while a pulse laser beam having a wavelength of 200 to 365 nm is applied from the condenser 524. When the application position of the condenser 524 of the laser beam application means 52 shown by a two-dotted chain line in FIG. 6 reaches the other end (right end in FIG. 6) of the dividing line 211, the application of the pulse laser beam is suspended and the movement of the chuck table 51, that is, the optical device wafer 2 is stopped. In this laser beam application step, the focusing point P of the pulse laser beam is set to a position near the front surface 21a (top surface) of the optical device wafer 2. As a result, a dividing groove 210 is formed in the optical device wafer 2 along the dividing line 211, as shown in FIG. 7.

The processing conditions in the above laser beam application step are set as follows, for example. Light source: LD excited Q switch Nd: YVO4 pulse laser Wavelength: 200 to 365 nm Pulse width: 5 to 350 ns Repetition frequency: 10 to 200 khz Average output: 1 to 10 W Focusing spot diameter: 1 to 10 μm Processing-feed rate: 10 to 600 mm/sec

A description will be made as to the wavelength of the pulse laser beam applied from the condenser 524 of the laser beam application means 52 hereinunder.

The inventor of the present invention has paid attention to the fact that the wavelength of light emitted from a gallium nitride optical element itself is 365 nm. That is, the inventor has found that when a pulse laser beam having a wavelength of 365 nm or less is applied along the dividing lines of a gallium nitride substrate, optical energy of the pulse laser beam is absorbed to form a dividing groove along the dividing lines in the gallium nitride substrate. Meanwhile, it has been found that the optical energy of a pulse laser beam having a wavelength of less than 200 is absorbed by air and hence, does not contribute to the processing of the gallium nitride substrate. Therefore, it is desired to set the wavelength of the pulse laser beam applied to the gallium nitride substrate to a range of 200 to 365 m. Stated more specifically, it is possible to use pulse laser beams having wavelengths of 213 nm, 266 nm and 355 nm.

After the above laser beam application step is carried out along the predetermined dividing line 211 as described above, the chuck table 51, therefore, the optical device wafer 2 held on the chuck table 51 is moved a distance corresponding to the interval between dividing lines 211 in the indexing direction indicated by the arrow Y (indexing step) to carry out the above laser beam application. step. After the laser beam application step and the indexing step are thus carried out on all the dividing lines 211 extending in the predetermined direction of the optical device wafer 2, the chuck table 51, therefore, the semiconductor wafer 2 held on the chuck table 51 is turned at 900 and then, the laser beam application step and the indexing step are carried out on dividing lines 211 extending in a direction perpendicular to the above predetermined direction, thereby making it possible to form a dividing groove along all the dividing lines 211 of the optical device wafer 2.

What is claimed is:

1. A method of laser processing a gallium nitride substrate, for forming a dividing groove along dividing lines that section devices formed on a gallium nitride substrate, the method comprising the step of applying a pulse laser beam having a wavelength of 200 to 365 nm along the dividing lines that section the devices formed on the gallium nitride substrate.
